(19) United States
(12) Patent Application Publication
(10) Pub. No.: US 2016/0238929 A1
(43) Pub. Date: Aug. 18, 2016

(54) UV-PATTERNABLE HARD-COATING FOR TRANSPARENT CONDUCTIVE FILM

(71) Applicant: COVESTRO DEUTSCHLAND AG, Leverkusen (DE)

(72) Inventors: Axel SCHMIDT, Köln (DE); Susan Lu TIAN, Singapore (SG); Lily Liqi YANG, Singapore (SG); Shao Quiang TANG, Singapore (SG)

(21) Appl. No.: 15/026,411

(22) PCT Filed: Sep. 26, 2014
(86) PCT No.: PCT/EP2014/070596

§ 371 Date: Mar. 31, 2016

(30) Foreign Application Priority Data
Oct. 1, 2013 (EP) 13186966.1

(51) Int. Cl. G03F 7/035; G03F 7/20; G03F 7/32; G03F 7/16

(52) U.S. Cl. CPC G03F 7/035; G03F 7/161; G03F 7/20; G03F 7/32

(57) ABSTRACT

The present invention relates to the substrates with UV-patternable hard-coating (UPHC) with, either on top or below the transparent conductive materials such as transparent conductive oxides (TCO), conductive polymers, carbon or metal based nanomaterials and nanocomposites, the process for its preparation and articles that comprise said substrates.

The present invention relates to substrates with UV-patternable hard-coating (UPHC) with either on top or underneath of it transparent conductive materials such as transparent conductive oxides (TCO), conductive polymers, carbon or metal based nanomaterials and nanocomposites, the process for its preparation and articles that comprise said substrates.

The traditional indium tin oxide (ITO) patterning must go through multiple and expensive photolithography steps and includes an etching process that uses commercial ITO etchant, which contains strong acid and oxidizer. This secondary processing may lead to occupational hazards and it is not environmental friendly. The high cost and many steps of ITO patterning trigger the revolution on more simple procedures with much lower cost.

Cambrios Technologies developed the silver nanowires (Ag NW) coating for transparent conductive films. WO2011106438 A1, WO2008046058 A2 and US20110088770 A1 disclose the use of monocure PUR coating (UV cured in one step) as an overcoat to protect the Ag NW coating. The transparent conductive films with Ag NW coating and monocure overcoat still go through exactly the same tedious and high cost patterning process like the ITO films.

There are several other companies applying the so-called “upside-down” process, like Innova Dynamics who describe in WO2011106730 A2 the embedding of the Ag NW into a heated substrate like polycarbonate, or Panasonic, who disclose in JP2011029038 A the coating of Ag NW with or without nanoparticles (NP) into a resin coated substrate. In JP2011065765 A, Konica Minolta describes the coating of a substrate with transparent resin and then burying Ag NW into the resin. WO2010130986 A by DuPont Teijin discloses coating a heat sealable co-extruded layer on PET substrate and Ag NW being heated and embedded into the binding layer. The processes described in this document use the same subtractive patterning by lithography as for ITO films.

In some prior art, such as in JP 2010232628 A, where a photoresist is used, there are two etching steps, once to etch away the unwanted areas during development, and in the second, to remove the areas of photo-resist left intact in the first step, consequently removing the conductive material that has been deposited on top of the photo-resist.

In U.S. Pat. No. 5,378,298 B, Motorola has also developed a radiation-curable adhesive, which is to be partially cured by heat after coating on a substrate before exposure to UV for patterning. There is, however, an additional step of thermal-curing after development, to complete the curing of the adhesive. This results in a three step-curing. There are some other examples where a last step of high temperature baking is done to form crystalline forms of certain oxides materials to achieve conductivity, such as indium-doped tin oxides. In these examples such as in JP 2001143526 A, only glass or ceramic substrates may be used due to the high temperatures used.

In CN 2013013566 A, Henkel China has developed a photo-curable adhesive, which can temporarily hold a carrier onto a substrate, and can be washed and removed by organic solvents when uncured by UV. This invention allows a simplification of the conductive patterns development, where there is only one step of washing and removal of the adhesive, after UV-curing and ITO deposition. However, there is also a step of removing the carrier. The adhesive may not have good blocking resistance which is a necessary for storage.

US 2007/0123613 A1 relates to coated post-formable films, to surface-coating compositions for such films, to a combined method for curing the surface-coating compositions and for post-forming, as well as to moulded bodies produced from the coated films.

Therefore there is a need for new patentable coated substrates that can be easily manufactured, show good chemical and scratch resistance and the required surface and optical properties. A further objective of this invention is to provide a process for the preparation of said transparent coated substrates that allows easy patterning. In this invention, UV-patternable hard-coating is applied, either on top or underneath of a transparent conductive material. The objective of this invention is to provide a UV-patternable hard-coating which enables easier patterning with less yield loss, with fewer process steps and avoids the use of strong acid or oxidizer. It is furthermore the objective of this invention to provide a process that reduces the likelihood of occupational hazards/pollution compared to the process established for ITO films.

The above problem is solved by the inventions as laid out in the independent claims while the dependent claims describe embodiments of the invention.

In particular, the problem is solved by substrates coated with at least one transparent conductive material layer and at least one hard-coating layer, characterized in that the hard-coating layer is a block-resistant thermoplastic layer and is end-cured by subsequent polymerization induced by actinic radiation comprising:
A) one or more monomeric or polymeric compounds that carry at least one functional group, that react with ethylenically unsaturated compounds under the action of actinic radiation, with polymerization, which compounds
   A1) contain at least one chemical function a) suitable for polyaddition with component B) and different from b) and/or
   A2) do not contain chemical function a) and optionally
B) one or more compounds containing at least one chemical function b) suitable for polyaddition with component A1) and different from a), which compounds
   B1) do not contain ethylenically unsaturated double bonds and/or
   B2) contain ethylenically unsaturated double bonds and
   C) silica nanoparticles,
   D) photoinitiators,
   E) additives such as stabilisers, catalysts and other auxiliary substances and additives,
   F) non-functional polymers and/or fillers.

The UV-patternable hard-coating can be produced by roll-to-roll coating process. This UV-patternable hard-coating is applied as transparent wet coating which has block resistance after drying and is suitable to be coated over with a layer of conductive material. The UV-patternable hard-coating is washable by common solvents and UV curable which makes it chemically resistant against the process of development by solvent-wash, resulting in the formation of relief patterns on the substrate. Where there is a layer of conductive material above or below the hard-coating, conductive patterns are obtained by non-contact washing with common solvents without traditional lithography-etching process. The hazardous strong acid, strong oxidizer or commercial etchant can be avoided during the patterning.

In one embodiment of the invention, the substrates are directly in contact with the transparent conductive material and the hard-coating is in contact with said transparent conductive material.

In another embodiment of the invention, the substrates are directly in contact with the hard-coating and the transparent conductive material is in contact with said hard coating.

The transparent conductive material and the hard-coating after final curing by actinic radiation form a chemically crosslinked conductive layer irrespective of the hard-coating being on top or underneath the transparent conductive material layer as long as the layers are in direct contact with one another. This way, substrates with a transparent conductive layer become available that are chemically resistant and scratch resistant and show a good homogeneous surface.

The conductive layers can be uniform throughout the surface of the substrate or can be in the form of patterns.

In another embodiment of the invention, the substrates may carry more than one conductive layers on top of one another. These can be either separated from one another by another isolating layer or patterned in a way that the more than one conductive layers do not interfere or overlap.

In the case of different isolated conductive layers, they can be either uniform or at least one of them can be patterned according to need.

In another embodiment of the invention, the substrate can be coated in both sides with at least one conductive layer. These again may be uniform or patterned according to need, irrespective of side or conductive layer if several are on one or both sides.

The UV-patternable hard-coating achieves easier patterning with less yield loss, with fewer and simple steps and avoiding the use of strong acid or oxidizer. It has less occupational hazards or cause less pollution compared to the standard process of manufacturing ITO films.

The UV-patternable hard-coating provides a lot of freedom for the patterning, and process for creating conductive relief patterns is simplified and shortened by one step with use of UV-patternable hard-coating.

With the traditional lithography-etching patterning method as used in the semiconductor, the photo-resist layer is usually etched twice, once to create a positive or negative photoresist image over the conductive material to be patterned, and for the second time, to remove the photo-resist. The UV-patternable hard-coating is only washed once by organic solvents under ultrasonic agitation, to create the patterns in which exists the conductive material, embedded in or adhered atop the hard-coating material layer or submerged under the hard-coating. This single non-contact washing step simultaneously removes both the electrically conductive material and the hard-coating material, in areas where the coating is shielded from the UV radiation by the chromed areas of the photo-mask.

The solvents used for washing the UV-patternable hard-coating are comparatively less harmful to the environment and human health than the strong acids and alkalis. The conductivity of the UV-irradiated areas is maintained to an acceptable level, even over extended periods of time. The new patterning process is capable of producing patterns with mostly smooth edges, with edge roughness as low as 2 μm and below, preferably below 1,5 μm, most preferably below 1,0 μm.

The block resistant UV-patternable hard-coating surface is non-sticky or non-tacky, and can be stored conveniently and used at a later time in the next step of the process which is the coating of the conductive material over the hard-coating layer. After the conductive material is coated by wet or dry coating method, the film remains optically clear, and possesses desired conductivity and block-resistance.

Inventive transparent conductive materials are PEDOT:PSS, ITO, silver nanowire, silver nano particles, indium tin oxide (ITO), fluorine tin oxide (FTO), aluminium doped zinc oxide (AZO) and antimony tin oxide (ATO). PEDOT—poly(3,4-ethylenedioxythiophene)—is a conducting polymer based on 3,4-ethylenedioxythiophene monomer. Its poor solubility is partly circumvented in the polystyrene sulfonate (PSS) PEDOT:PSS combination, and in the tetramethacrylate (TMA) end-capped PEDOT-TMA material.

Accordingly, in an embodiment of the invention the substrate is patterned with conductive areas and non-conductive areas. Conductive areas are areas which show a sheet resistance of 3000106 /□ and less, and more preferably, 500Ω/□ and less. Non-conductive areas for the purpose of this invention are those that exhibit a sheet resistance of 4×10 ¹⁰Ω/□ and more, and more preferably, 4×10²⁸Ω/□ and more.

The sheet resistance measured with a resistivity meter according to standard proceeding ASTM D257-93.

The invention also relates to a process for the preparation of a substrate coated with a conductive layer.

The inventive process for the preparation of a coated substrate is characterized by the steps in the following sequence:
(a) coating said substrate with a transparent conductive material,
(b) coating said transparent conductive material with a hard-coating precursor,
(c) thermally curing said hard-coating precursor,
(d) end-curing said hard-coating by actinic radiation.

In another embodiment of the inventive process the steps are made in the following sequence:
(a1) coating said substrate with a hard-coating precursor and
(b1) thermally curing said hard-coating precursor,
(c1) coating said thermally cured hard-coating with a transparent conductive material,
(d1) end-curing said hard-coating by actinic radiation or
(a1) coating said substrate with a hard-coating precursor,
(b1) thermally curing said hard-coating precursor,
(c1) end-curing said hard coating,
(d1) coating said thermally cured hard-coating with a transparent conductive material.

The process yields a substrate coated with a uniform conductive chemically and scratch resistant conductive layer.

In a further embodiment of the inventive process, the thermally cured hard coat precursor is patterned by applying a physical mask on the top surface during end-curing with actinic radiation in step (d) and subsequent solvent washing of the coated substrate. This washing removes the only thermally cured hard coat layers along with the transparent conductive material layer and exposes these areas of the substrate as non-conductive areas, while the actinically cured areas are conductive resulting in a pattern of conductive and non-conductive areas.

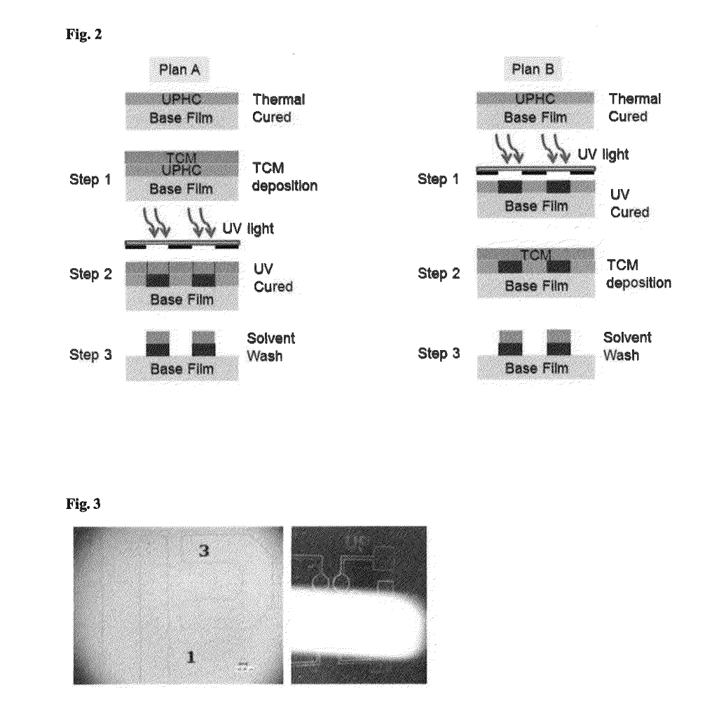

In the case where the conductive layer is above the UV-patternable hard-coating, the process of developing conductive patterns can be done in two variations. In the first scheme (so-called Plan A as shown in FIG. 2), the UV-patternable hard-coating is coated with a layer of conductive material before UV irradiation through a photomask, followed by pattern development via washing. In the second scheme (so-called Plan B as shown in FIG. 2), the UV-patternable hard-coating is first irradiated with UV through a photomask, before being coated with a layer of conductive material, followed by pattern development via washing.

The core of the invention is the block-resistant, UV-patternable and solvent washable hard-coating for transparent conductive films. This transparent wet coating forms block-resistance after thermal curing for example within 5-30 min at low process temperature range, for example at 100-150° C., but is still washable by organic solvent, which facilitates the patterning process later on. The UV curing of selected surface areas (patterns) by radical polymerization of radically polymerizable monomers e.g. acrylates, within seconds, achieves higher crosslink density. After UV curing, the cured surface areas (patterns) of the coating are resistant to the solvent washing, so they can act well as the protection layer over the transparent conductive coating or as the supportive layer underneath the transparent conductive coatings. The coated films can be realized by suitable coater, e.g. slot die coater, through roll-to-roll process with high productivity and efficiency.

The invention accordingly provides a UV patternable hard-coating for transparent conductive films. The invention further provides a combined method for curing the surface coating compositions and for patterning, the use thereof, and moulded articles produced from the coated films.

The hard-coating compositions are pre-cured to form a blocking-resistant and thermoplastic layer and are finally end-cured by subsequent polymerization initiated by actinic radiation, they comprise:
A) one or more monomeric or polymeric compounds that carry at least one functional group, that react with ethylenically unsaturated compounds under the action of actinic radiation, with polymerization, which compounds
   A1) contain at least one chemical function a) suitable for polyaddition with component B) and different from b) and/or
   A2) do not contain chemical function a) and optionally
B) one or more compounds containing at least one chemical function b) suitable for polyaddition with component A1) and different from a), which compounds
   B1) do not contain ethylenically unsaturated double bonds and/or
   B2) contain ethylenically unsaturated double bonds and
   C) silica nanoparticles,
   D) photoinitiators,
   E) additives such as stabilisers, catalysts, wetting agents and other auxiliary substances and additives,
   F) non-functional polymers and/or tillers.

Suitable chemical functions a) and b) for the polyaddition are in principle any functions (chemical moieties) conventionally used in coating technology. Isocyanate-hydroxyl/thiol/amine, carboxylate-epoxide, melamine-hydroxyl and carbamate-hydroxyl are particularly suitable. As a) very particular preference is given to hydroxyl, primary and/or secondary amines and asparaginate, function b), very particular preference is given to isocyanates, also in blocked form, and as function.

As component A) there are suitable one or more monomeric or polymeric compounds that carry at least one functional group, that react with ethylenically unsaturated compounds under the action of actinic radiation, with polymerization. Such compounds are, for example, esters, carbonates, acrylates, ethers, urethanes or amides or polymeric compounds of those structural types. It is also possible to use any desired mixtures of such monomers and/or polymers that contain at least one group polymerisable under the action of actinic radiation.

As compounds of component A) there can be used modified monomers or polymers, the modification of which is effected by methods known per se. In the modification, appropriate chemical functionalities are introduced into the molecules. There are suitable α,β-unsaturated carboxylic acid derivatives, such as acrylates, methacrylates, maleates, fumarates, maleimides, acrylamides, also vinyl ethers, propenyl ethers, allyl ethers and dicyclopentadienyl-unit-containing compounds. Vinyl ethers, acrylates and methacrylates are preferred, and acrylates are particularly preferred. Examples include the reactive diluents known in the technology of radiation curing (see Römpp Lexikon Chemie, p. 491, 10th Ed. 1998, Georg-Thieme-Verlag, Stuttgart) or the binders known in the technology of radiation curing, such as polyether acrylates, polyester acrylates, urethane acrylates, epoxy acrylates, melamine acrylates, silicone acrylates, polycarbonate acrylates and acrylated polyacrylates.

Suitable esters are conventionally obtained by esterification of alcohols having from 2 to 20 carbon atoms, preferably polyhydric alcohols having from 2 to 20 carbon atoms, with unsaturated acids or unsaturated acid chlorides, preferably acrylic acid and derivatives thereof. To that end, the esterification methods known to the person skilled in the art can be used.

Suitable alcohol components in the esterification are monohydric alcohols, such as the isomers of butanol, pentanol, hexanol, heptanol, octanol, nonanol and decanol, also cycloaliphatic alcohols, such as isobornol, cyclohexanol and alkylated cyclohexanols, dicyclopentanol, arylaliphatic alcohols, such as phenoxyethanol and nonylphenylethanol, as well as tetrahydrofurfuryl alcohols. Also suitable are dihydric alcohols, such as ethylene glycol, 1,2-propanediol, 1,3-propanediol, diethylene glycol, dipropylene glycol, the isomers of butanediol, neopentyl glycol, 1,6-hexartediol, 2-ethylhexartediol, 1,4-cyclohexatiediol, 1,4-cyclohexaneditnethanol and tripropylene glycol. Suitable higher hydric alcohols are glycerol, trimethylolpropane, ditrimethylolpropane, pentaerythritol or dipentaerythritol. Preference is given to diols and higher hydric alcohols, particular preference being given to glycerol, trimethylolpropane, pentaerythritol, dipentaerythritol and 1,4-cyclohexanedimethanol.

Suitable esters and urethanes are, for example, also obtainable by reaction of unsaturated OH-functional, unsaturated compounds having from 2 to 12 carbon atoms, preferably from 2 to 4 carbon atoms, with acids, esters, acid anhydrides or acid chlorides or isocyanates.

There come into consideration as hydroxy-functional acrylates or methacrylates, for example, compounds such as 2-hydroxyethyl (meth)acrylate, polyethylene oxide mono(meth)acrylates, polypropylene oxide mono(meth)acrylates, polyalkylene oxide mono(meth)acrylates, poly(ε-caprolactone) mono(meth)acrylates, such as, for example, Tone® M100 (Dow, Schwalbach, DE), 2-hydroxypropyl (meth)acrylate, 4-hydroxybutyl(meth)acrylate, 3-hydroxy-2,2-dimethylpropyl(meth)acrylate, the hydroxy-functional mono-, di- or tetra-acrylates of polyhydric alcohols such as trimethylolpropane, glycerol, pentaerythritrol, dipentaerythritol, ethoxylated, propoxylated or alkoxylated trimethylolpropane, glycerol, pentaerythritol, dipentaerythritol or commercial mixtures thereof.

Examples of preferred unsaturated OH-functional compounds are hydroxyethyl(meth)acrylate, 2- and 3-hydroxypropyl(meth)acrylate, 2-, 3- and 4-hydroxybutyl(meth)acrylate, also OH-functional vinyl ethers, such as, for example, hydroxybutyl vinyl ether, and mixtures thereof.

It is further possible to use as OH-functional unsaturated compounds OH-functional (meth)acrylic acid esters or amides, which are obtainable by reaction of up to n-1 equivalents of (meth)acrylic acid with n-hydric alcohols, amines, amino alcohols and/or mixtures thereof. Suitable n-hydric alcohols are glycerol, trimethylolpropane and/or pentaerythritol.

Products from the reaction of epoxy-functional (meth)acrylic acid esters with (meth)acrylic acid can likewise be used. For example, the reaction of glycidyl methacrylate with acrylic acid yields a mixed acrylic acid-methacrylic acid ester of glycerol, which can be used particularly advantageously.

Mono-, di- or poly-isocyanates can be used for the preparation of urethanes from those OH-functional unsaturated compounds. There are suitable for that purpose the isomers of butyl isocyanate, butylene diisocyanate, hexamethylene diisocyanate (HDI), isophorone diisocyanate (IPDI), 2,2,4- and/or 2,4,4-trimethylhexamethylene diisocyanate, the isomers of bis(4,4′-isocyanatocyclohexyl)methane or mixtures thereof having any desired isomer content, isocyanatomethyl-1,8-octane diisocyanate, 1,4-cyclohexylene diisocyanate, the isomers of cyclohexanedimethylene diisocyanate, 1,4-phenylene diisocyanate, 2,4- and/or 2,6-toluylene diisocyanate, 1,5-naphthylene diisocyanate, 2,4′- or 4,4′-diphenylmethane diisocyanate, triphenylmethane-4,4′,4″-triisocyanate or derivatives thereof having a urethane, urea, carbodiimide, acylurea, isocyanurate, allophanate, biuret, oxadiazinetrione, uretdione, iminooxadiazinedione structure and mixtures thereof. Preference is given to polyisocyanates based on oligomerised and/or derivatised diisocyanates which have been freed of excess diisocyanate by suitable processes, in particular those of hexamethylene diisocyanate, isophorone diisocyanate and the isomers of bis(4,4′-isocyanatocyclohexyl)methane and mixtures thereof. Preference is given to the oligonneric isocyanurates, uretdiones, allophanates and iminooxadiazinediones of HDI, to the oligomeric isocyanurates, uretdiones and allophanates of IPDI and to the oligomeric isocyanurates of the isomers of bis(4,4′-isocyanatohexyl)methane and mixtures thereof.

In analogy to the above description, suitable polyesters, polycarbonates or polyurethanes are obtainable, for example, by reaction of unsaturated OH-functional compounds having from 2 to 12 carbon atoms, preferably from 2 to 4 carbon atoms, with, for example, acid-, ester- or acid-chloride-functional polyesters or polycarbonates or NCO-functional polyurethanes.

Also suitable are reaction products of polyesters having acid numbers >5 and glycidyl-functional (meth)acrylates (e.g. glycidyl methacrylate).

Preferred OH-functional unsaturated compounds for the synthesis of unsaturated polyesters, polycarbonates and polyurethanes are hydroxyethyl acrylate and the isomers of hydroxypropyl acrylate. Particular preference is given to the reaction product of glycidyl methacrylate and acrylic acid.

Polyacrylates can be modified for radiation curing only after polymerization of the acrylate and vinyl aromatic monomers. This is effected via functional groups that are inert with respect to the preparation conditions of the polyacrylate and are only subsequently modified further to unsaturated radiation-curing groups. Suitable groups for this purpose are, for example, those listed in the following table:

| Inert group | Modifying reagent | Radiation-curing group |
|---|---|---|
| Epoxy | Acrylic acid, dimeric acrylic acid | Acrylate |
| Acid | Glycidyl methacrylate | Methacrylate |
| Acid | Hydroxyalkyl acrylate | Acrylate |
| Alcohol | Maleic anhydride | Maleate |
| Alcohol | Acrylic acid, dimeric acrylic acid | Acrylate |
| Alcohol | Acrylic-functional isocyanate | Urethane acrylate |
| Isocyanate | Hydroxyalkyl acrylate | Urethane acrylate |
| Anhydride | Hydroxyalkyl acrylate | Acrylate |

It is further possible to use as compounds of component A) any compounds, individually or in any desired mixtures, that contain at least one group reactive towards isocyanates and at least one unsaturated function which reacts with ethylenically unsaturated compounds under the action of actinic radiation, with polymerization.

Preference is given to the use of α,β-unsaturated carboxylic acid derivatives, such as acrylates, methacrylates, maleates, fumarates, maleimides, acrylamides, as well as vinyl ethers, propenyl ethers, allyl ethers and dicyclopentadienyl-unit-containing compounds which have at least one group reactive towards isocyanates; these are particularly preferably acrylates and methacrylates having at least one isocyanate-reactive group.

Also suitable are hydroxy-functional acrylates or methacrylates, for example, compounds such as 2-hydroxyethyl(meth)acrylate, polyethylene oxide mono(meth)acrylates, polypropylene oxide mono(meth)acrylates, polyalkylene oxide mono(meth)acrylates, poly(ε-caprolactone) mono(meth)acrylates, such as, for example, Tone® M100 (Dow, Schwalbach, DE), 2-hydroxypropyl(meth)acrylate, 4-hydroxybutyl(meth)acrylate, 3-hydroxy-2,2-dimethylpropyl(meth)acrylate, the hydroxy-functional mono-, di- or tetra-acrylates of polyhydric alcohols such as trimethylolpropane, glycerol, pentaerythritol, dipentaerythritol, ethoxylated, propoxylated or alkoxylated trimethylolpropane, glycerol, pentaerythritol, dipentaerythritol or commercial mixtures thereof.

In addition, isocyanate-reactive oligomeric or polymeric unsaturated acrylate and/or methacrylate group-containing compounds, on their own or in combination with the above-mentioned monomeric compounds, are suitable.

The preparation of polyester acrylates is described in DE-A 4 040 290 (p. 3, 1.25-p. 6, 1.24), DE-A 3 316 592 (p. 5, 1.14-p. 11, 1.30) and P. K. T. Oldring (Ed.), Chemistry & Technology of UV & EB Formulations For Coatings, Inks & Paints, Vol. 2, 1991, SITA Technology, London, p. 123-135.

It is likewise possible to use the hydroxyl-group-containing epoxy(meth)acrylates having OH contents of from 20 to 300 mg KOH/g or hydroxyl-group-containing polyurethane(meth)acrylates having OH contents of from 20 to 300 mg KOH/g or acrylated polyacrylates having OH contents of from 20 to 300 mg KOH/g, in each case known per se, as well as mixtures thereof with one another and mixtures with hydroxyl-group-containing unsaturated polyesters and also mixtures with polyester(meth)acrylates or mixtures of hydroxyl-group-containing unsaturated polyesters with polyester(meth)acrylates. Such compounds are likewise described in P. K. T. Oldring (Ed.), Chemistry & Technology of UV & EB Formulations For Coatings, Inks and Paints, Vol. 2, 1991, SITA Technology, London p, 37-56. Polyester acrylates having defined hydroxy functionality are preferred.

Hydroxyl-group-containing epoxy(meth)acrylates are based in particular on reaction products of acrylic acid and/or methacrylic acid with epoxides (glycidyl compounds) of monomeric, oligomeric or polymeric bisphenol A, bisphenol F, hexanediol and/or butanediol or their ethoxylated and/or propoxylated derivatives. Preference is further given to epoxy acrylates having defined functionality, such as those from the reaction of an optionally unsaturated dioic acid, such as fumaric acid, maleic acid, hexahydrophthalic acid or adipic acid, and glycidyl (meth)acrylate. Aliphatic epoxy acrylates are particularly preferred. Acrylated polyacrylates can be prepared, for example, by reaction of glycidyl-functional polyacrylates with (meth)acrylic acid.

As compounds of component A1) there can be used any of the above-mentioned isocyanate-reactive compounds A), individually or in any desired mixtures, that do not contain ethylenically unsaturated functions.

As compounds of component A2) there can be used any of the above-mentioned compounds A), individually or in any desired mixtures, that contain at least one isocyanate-reactive group and additionally at least one ethylenically unsaturated function which reacts with ethylenically unsaturated compounds under the action of actinic radiation, with polymerization.

As component B) there are used aromatic, araliphatic, aliphatic and cycloaliphatic di- or poly-isocyanates. It is also possible to use mixtures of such di- or poly-isocyanates. Examples of suitable di- or poly-isocyanates are butylene diisocyanate, hexamethylene diisocyanate (HDI), isophorone diisocyanate (IPDI), 2,2,4- and/or 2,4,4-trimethylhexatnethylene diisocyanate, the isomers of bis(4,4′-isocyanatocyclohexyl)methane and mixtures thereof having any desired isomer content, isocyanatomethyl-1,8-octane diisocyanate, 1,4-cyclohexylene diisocyanate, the isomers of cyclohexanedimethylene diisocyanate, 1,4-phenylene diisocyanate, 2,4- and/or 2,6-toluylene diisocyanate, 1,5-naphthylene diisocyanate, 2,4′- or 4,4′-diphenylmethane diisocyanate, triphenylmethane-4,4′,4″-triisocyanate or derivatives thereof having a urethane, urea, carbodiimide, acylurea, isocyanurate, allophanate, biuret, oxadiazinetrione, uretdione, iminooxadiazinedione structure and mixtures thereof. Preference is given to polyisocyanates based on oligomerised and/or derivatised diisocyanates which have been freed of excess diisocyanate by suitable processes, in particular those of hexamethylene diisocyanate, isophorone diisocyanate and the isomers of bis(4,4′-isocyanatocyclohexyl)methane and mixtures thereof. Preference is given to the oligomeric isocyanurates, uretdiones, allophanates and iminooxadiazinediortes of HDI, of IPDI and/or of the isomers of bis(4,4′-isocyanatocyclohexyl)methane and mixtures thereof. Particular preference is given to the oligomeric isocyanurates, uretdiones and allophanates of IPDI and to the oligomeric isocyanurates of the isomers of bis(4,4′-isocyanatohexyl)methane.

It is optionally also possible to use the above-mentioned isocyanates B) partially reacted with isocyanate-reactive ethylenically unsaturated compounds. There are used for this purpose preferably α,β-unsaturated carboxylic acid derivatives, such as acrylates, methacrylates, maleates, fumarates, maleimides, acrylamides, as well as vinyl ethers, propenyl ethers, allyl ethers and dicyclopentadienyl-unit-containing compounds which have at least one group reactive towards isocyanates; these are particularly preferably acrylates and methacrylates having at least one isocyanate-reactive group. There come into consideration as hydroxy-functional acrylates or methacrylates, for example, compounds such as 2-hydroxyethyl(meth)acrylate, polyethylene oxide mono(meth)acrylates, polypropylene oxide mono(meth)acrylates, polyalkylene oxide mono(meth)acrylates, poly(“epsilon”-caprolactone) mono(meth)acrylates, such as, for example, Tone® M100 (Dow, USA), 2-hydroxypropyl (meth)acrylate, 4-hydroxybutyl(meth)acrylate, 3-hydroxy-2,2-dimethylpropyl(meth)acrylate, the hydroxy-functional mono-, di- or tetra-(meth)acrylates of polyhydric alcohols such as trimethylolpropane, glycerol, pentaerythritol, dipentaerythritol, ethoxylated, propoxylated or alkoxylated trimethylolpropane, glycerol, pentaerythritol, dipentaerythritol or commercial mixtures thereof. In addition, isocyanate-reactive oligomeric or polymeric unsaturated acrylate and/or methacrylate-group-containing compounds, on their own or in combination with the above-mentioned monomeric compounds, are suitable.

It is optionally also possible to use the above-mentioned isocyanates B) partially reacted with blocking agents known to the person skilled in the art from coating technology. Examples of blocking agents which may be mentioned include: alcohols, lactams, oximes, malonic esters, alkyl acetoacetates, triazoles, phenols, imidazoles, pyrazoles and amines, such as, for example, butanoneoxime, diisopropylamine, 1,2,4-triazole, dimethyl-1,2,4-triazole, imidazole, malonic acid diethyl ester, acetic acid ester, acetone oxime, 3,5-dimethylpyrazole, epsilon-caprolactam, N-tert-butyl-benzylamine, cyclopentanone carboxyethyl ester or any desired mixtures of these blocking agents.

The mean number of functional groups a), that is to say, for example, of isocyanate groups, per molecule (functionality) of component B) that is used is in each case >2.0, preferably from 2.0 to 4.0, particularly preferably from 3.0 to 4.0.

As compounds of component B1) there can be used any of the above-mentioned di- or poly-isocyanates B), individually or in any desired mixtures, that do not contain ethylenically unsaturated functions.

As compounds of component B2) there can be used any of the above-mentioned compounds B), individually or in any desired mixtures, that has at least one isocyanate group and in addition at least one ethylenically unsaturated function which reacts with ethylenically unsaturated compounds under the action of actinic radiation, with polymerization.

As compound C) there can be used any silica nanoparticles in form of powder, solvent dispersion or water dispersion. The nanoparticles should be compatible and miscible with the coating agent. The mean particle size that is to say, for example, of nanoparticles, is used is in each case from 1 nm to 1000 nm, preferably from 10 nm to 100 nm, particularly preferably from 10 nm to 20 nm.

Photoinitiators D are initiators which can be activated by actinic radiation and initiate free-radical polymerization of the corresponding polymerisable groups. Photoinitiators are commercially available compounds known per se, a distinction being made between unimolecular (type I) and bimolecular (type II) initiators. (Type I)-systems are, for example, aromatic ketone compounds, for example benzophenones in combination with tertiary amines, alkylhenzophenones, 4,4′-bis(dimethylamino)benzophenone (Miehler's ketone), anthrone and halogenated benzophenones or mixtures of the mentioned types. Also suitable are (type II)-initiators, such as benzoin and its derivatives, benzil ketals, acylphosphine oxides, for example 2,4,6-trimethyl-benzoyl-diphenylphosphine oxide, bisacylophosphine oxides, phenylglyoxylic acid esters, camphorquinone, α-aminoalkylphenones, α,α-dialkoxyacetophertones and α-hydroxyalkylphenones. It can also be advantageous to use mixtures of these compounds. Depending on the radiation source used for curing, the type and concentration of photoinitiator must be adapted in the manner known to the person skilled in the art. Further details are described, for example, in P. K. T. Oldring (Ed.), Chemistry & Technology of UV & EB Formulations For Coatings, Inks & Paints, Vol. 3, 1991, SITA Technology, London, p. 61-328.

As component E) there can be present additives or auxiliary agents conventional in the technology of surface coatings, paints, inks, sealing materials and adhesives.

In particular, they are stabilisers, light stabilisers, such as UV absorbers and sterically hindered amines (HALS), also antioxidants and auxiliary substances for surface-coating compositions, for example antisettling agents, antifoams and/or wetting agents, flow agents, plasticisers, catalysts, solubilisers and/or thickeners as well as pigments, colourings and/or delustering agents. The use of light stabilisers and the various types thereof are described, for example, in A. Valet, Lichtschutzmittel für Lacke, Vincentz Verlag, Hanover, 1996.

As component F) there can be present non-functional polymers and fillers for adjusting the mechanical and optical properties. All polymers and fillers that are compatible and miscible with the coating agent are suitable for this purpose. The compounds of component F can be used both as bulk material and in the form of particles having mean diameters in the range from one to 1,000 nanometres, preferably in the range from 10 to 100 nanometres, particularly preferably in the range from 10 to 20 nanometres.

Suitable polymeric additives are polymers such as, for example, polyacrylates, polycarbonates, polyurethanes, polyolefins, polyethers, polyesters, polyamides and polyureas.

There can be used as fillers mineral fillers, glass fibres and/or metallic fillers, as are employed in conventional formulations for so-called metallic surface coatings.

The substrate for the coating composition according to the invention serves as the carrier material for the composite material that is formed and, in addition to general fastness requirements, must possess above all the necessary thermal formability. In principle, therefore, inorganic substrates like ceramics or mineral glass, thermosetting polymers and thermoplastic polymers, such as ABS, AMMA, ASA, CA, CAB, EP, UF, CF, MF, MPF, PF, PAN, PA, PE, HDPE, LDPE, LLDPE, PC, PET, PMMA, PP, PS, SB, PUR, PVC, RF, SAN, PBT, PPE, POM, PP-EPDM and UP (abbreviations in accordance with DIN 7728 part 1) and mixtures thereof, in particular polyacrylates, polymethacrylates, thermoplastic polyurethanes, polycarbonates, polyesters, polyethers, polyolefins, polyamides, copolymers of different polymers and blends of different polymers are suitable. Thermoplastic polyurethanes, polymethyl methacrylate (PMMA) and modified variants of PMMA, polycarbonates, acrylstyrene-acrylonitrile copolymers (ASA), polyethylene terephthalate (PET), polypropylene (PP), polypropylene-ethylene propylene diene monomer rubber copolymers (PP-EPDM) and acrylonitrile-butadiene-styrene copolymers (ABS) and mixtures of these polymers are particularly suitable. In another embodiment of the invention, the substrate comprises one of the aforementioned carriers and is coated with a coating, e.g. a scratch-resistant or protective coating, also shortly called coated substrate.

Substrates according to the invention encompass inorganic substrates, in particular ceramics or mineral glass; thermosetting polymers and thermoplastic polymers, in particular polyacrylates, polymethacrylates, polycarbonates, polyethylene terephthalate, thermoplastic polyurethanes, polyesters, polyethers, polyolefins, polyamides, copolymers of different polymers and blends of different polymers and coated substrates.

The substrate may be in any form, as well in the form of a 3-dimensional object, in one embodiment it is a form with 2-dimensional areas like a block, a pane or a sheet, in another embodiment the form is a film. Films can be monolayered or laminated films constructed from two or more layers of the mentioned plastics. In general, the films to be used according to the invention may also contain reinforcing fibres or fabrics, provided that these do not impair thermoplastic deformation. A film for the purpose of this invention has a thickness of from 10 μm to 3000 μm, more preferably from 50 μm to 1000 μm and particularly preferably from 50 μm to 300 μm.

In addition, the material of the film may contain additives and/or processing auxiliaries for film production, such as e.g. stabilisers, light stabilisers, plasticisers, fillers such as fibres, and dyes. The side of the film intended for coating as well as the other side may be smooth or may exhibit a surface structure, a smooth surface being preferred for the side to be coated. In one embodiment of the invention both sides of the film are coated with a conductive layer.

The substrate may be coated at single side or double to enhance mechanical properties, e. g scratch resistance, or to build in special optical effect, e. g. anti-glare, anti-reflection.

Transparent conductive materials according to the invention may comprise conductive nanoparticles, nanowires, conductive polymers, transparent conductive oxides, carbon or metal based nanomaterials and nanocomposites.

A blocking-resistant coating is a coating that does not tend to adhere to itself (see Zorn (Ed.), Römpp Lexikon Lacke und Druckfarben, 10th Ed., p. 81, Georg Thieme Verlag, Stuttgart, 1998).

Blocking resistance can be determined by test methods as described e.g. in DIN 53150,

A further test method to simulate the blocking resistance of rolled, pre-dried lacquered films can be determined as follows. The lacquer materials were applied using a commercial doctor knife (required wet coat thickness 100 μm) to Makrofol DE 1-1 films (375 μm). Following a solvent evaporation phase of 10 mm at 20° C. to 25° C., the lacquered films were dried for 10 min at 110° C. in a circulating air oven. After a cooling phase of 1 min, a commercial adhesive laminating film GH-X173 natural (Bischof und Klein, Lengerich, Germany) was applied crease-free onto the dried lacquered film using a plastic paint roller over an area of 100 mm×100 mm. The laminated film section was then loaded over the entire surface with a 10 kg weight for 1 hour. After this, the laminating film was removed and the lacquer surface was evaluated visually.

A thermoplastic substance is a substance which exhibits, above its use temperature, a reversible softening point or range above which it can be mechanically formed, the new form being retained after cooling of the substance below the softening point or range. In general, thermoplastic behaviour of polymeric substances requires a linear and/or branched structure of the polymeric units. Crosslinked polymers, on the other hand, no longer exhibit thermoplastic behaviour even at low degrees of crosslinking, but exhibit duromeric behaviour, that is to say they are not thermally formable at all or only to a small degree.

The invention relates also to a combined method for curing the surface-coating compositions and for post-forming the coating composition according to the invention. The step of forming the conductive transparent layer is not explicitly mentioned here, but it can be done either before or after the application of the coating layer as described before.

The coating composition according to the invention may be first applied to the substrate film (film) by conventional methods such as knife application, roller application, spraying or printing. The applied layer thicknesses (before curing) are typically from 1 to 100 μm, preferably from 2 to 20 μm, particularly preferably from 4 to 10 μm.

This is followed by a first thermal curing step to form a block-resistant coating having thermoplastic property.

After the first thermal curing step, the coated film can be brought into the desired final form by thermal forming. This can be effected according to conventional processes such as deep-drawing, thermoforming, vacuum forming, high pressure forming, compression moulding, blow moulding (see Lechner (Ed.), Makromolekulare Chemie, p. 384 ff, Verlag Birkenhauser, Basle, 1993). In addition, the coated film can optionally he used in the heated state for coating objects.

After the forming step, the coating of the coated film is finally cured by irradiation with actinic radiation.

Curing by means of actinic radiation is understood as being the free-radical polymerization of ethylenically unsaturated carbon-carbon double bonds by means of initiator radicals which, for example, are liberated from the above-described photoinitiators by actinic radiation, in particular visible and/or UV light.

Radiation curing is preferably carried out by the action of high-energy radiation, that is to say UV radiation or daylight, for example light having a wavelength of from 200 to 750 nm, or by irradiation with high-energy electrons (electron radiation, 90 to 300 keV). As radiation sources for light or UV light there are used, for example, medium- or high-pressure mercury vapour lamps, it being possible for the mercury vapour to be modified by doping with other elements, such as gallium or iron. Lasers, pulsed lamps (known by the name UV flashlight radiators), halogen lamps or excimer radiators can likewise be used. The radiators can be installed in a stationary manner, so that the material to be irradiated is moved past the radiation source by means of a mechanical device, or the radiators can be movable and the material to be irradiated does not change position during curing. The radiation dose that is conventionally sufficient for crosslinking in the case of UV curing is in the range from 80 to 5000 mJ/cm².

The irradiation can optionally be carried out with the exclusion of oxygen, for example under an inert gas atmosphere or an oxygen-reduced atmosphere. Suitable inert gases are preferably nitrogen, carbon dioxide, noble gases or combustion gases. The irradiation can further be carried pattern out by covering the coating with media that are transparent to radiation. Examples thereof are plastics films, glass or liquids such as water.

The type and concentration of the initiator that is optionally used are to be varied or optimised in a manner known to the person skilled in the art by orientating preliminary experiments, according to the radiation dose and the curing conditions. For curing of the formed films it is particularly advantageous to carry out the curing using a plurality of radiators, the arrangement of which is to be so chosen that, where possible, every point of the coating receives the optimum dose and intensity of radiation for curing. In particular, non-irradiated regions (shaded areas) are to be avoided, except for those areas that are predetermined for being patterned.

Mercury radiators in stationary devices are particularly preferably used for the curing. Photoinitiators are then employed in concentrations of from 0.1 to 10 wt. %, particularly preferably from 0.2. to 3.0 wt. %, based on the solids of the coating. For the curing of such coatings, a dose of from 500 to 4000 mJ/cm², measured in the wavelength range from 200 to 600 nm, is preferably used.

After end-curing the 3-dimensionally formed substrate can be (rear) injected with thermoplastic material or thermoplastic material foams to produce articles.

Another object of the invention are articles comprising said substrates or articles comprising substrates obtainable or obtained according to the described process of manufacturing the substrates or articles with 3-dimensional shape obtainable according to the process of forming and (rear) injection of the formed substrate.

The invention is illustrated by the following figures without limiting the invention to the respective represented embodiments.

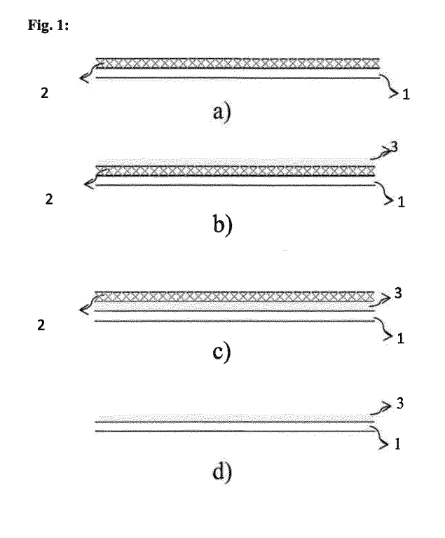

FIG. 1: Film construction
FIG. 1a) shows a substrate (1) with a transparent conductive material layer (2).
FIG. 1b) shows a substrate (1) with a transparent conductive material layer (2) and on top of the transparent conductive material (2) the UV patternable hard coating (3).
FIG. 1c) shows a substrate (1) with a UV patternable hard coating (3) and on top of it a transparent conductive material layer (2).
FIG. 1d) shows a substrate (1) with a UV pattemable hard coating (3) on top.

FIG. 2: Two different schemes for the formation of transparent conductive thin films

FIG. 3: Developability for reference example 1 with substrate (1) and UV patternable hard coat (UPHC) (3): Edge roughness=1.66 μm

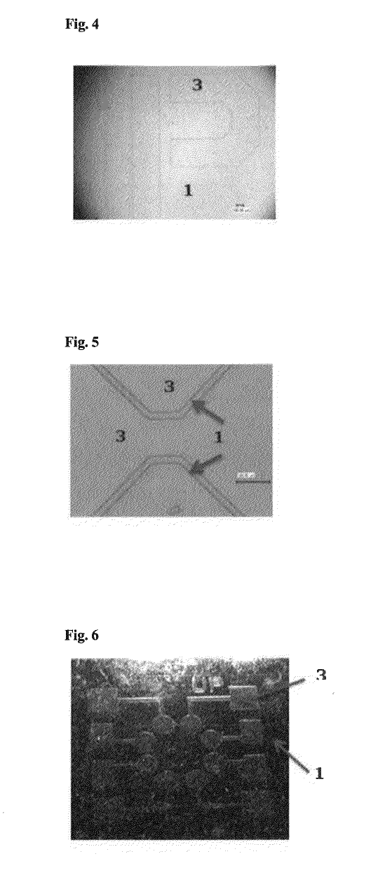

FIG. 4: Developability for reference example 2 with substrate (1) and UV pattemable hard coat (UPHC) (3): Edge roughness=0.84 μm

FIG. 5: Developability for reference example 2 with substrate (1) and UV pattemable hard coat (UPHC) (3): Patterns on UPHC for touch screen panels

FIG. 6: Developability for reference example 3 with substrate (1) and UV patternable hard coat (UPHC) (3): Edge roughness=1.3 μm

FIG. 7: Developability for example 1 with substrate (1) and UV patternable hard coat and ITO layer (UPHC-ITO) (3a): Edge roughness=1.9 μm

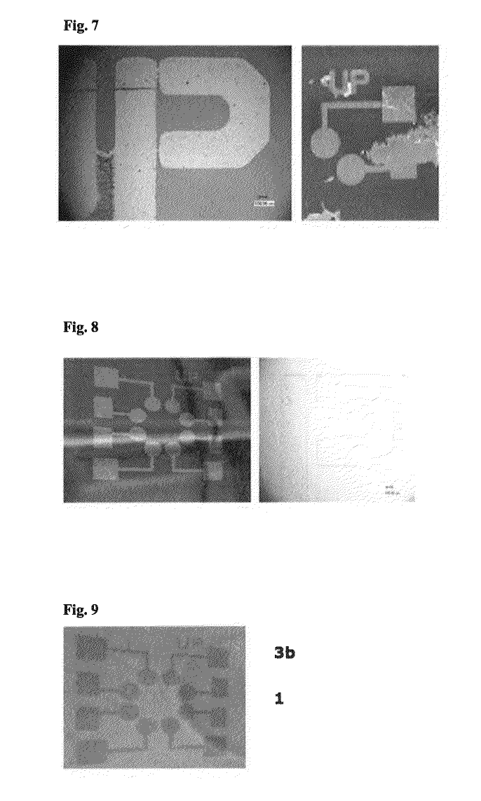

FIG. 8: Developability for Example 2 with substrate (1) and UV patternable hard coat and ITO layer (UPHC-ITO) (3a): Edge roughness=1.4 μm

FIG. 9: Developability for example 4 with substrate (1) and UV patternable hard coat and PEDOT layer (UPHC-PEDOT) (3b): Edge roughness=1.4 μm

### EXAMPLES

All percentages are given based on the weight.

Materials:

Bayhydrol UV XP 2720/1 is anionic UV-curable polyurethane dispersion in water by Bayer MaterialScience AG;

Bayhydrol UH XP 2648 is an aliphatic, anionic polyurethane dispersion containing polycarbonate in water by Bayer MaterialScience AG;

4-Hydroxy-4-methyl-pentanone is a solvent by Kraemer & Martin GmbH;

1-Methoxy-2-propanol is a solvent by Kraemer & Martin GmbH;

Tegoglide 410 is a flow promoter by Evonik Tego Chemie GmbH;

BYK 346 is a wetting agent by BYK Chemie;

Irgacure 500 is a photoinitiator by BASF;

Borchi-gel 625 is a non-ionic, polyurethane-based thickener free of alkylphenol etboxylate (APEO);

Bindzil cc401 is a water based silica nanoparticle dispersion by AkzoNobel;

Dimethylethanolamine is a pH value adjuster by Sigma Aldrich;

Ebecryl 1200 acrylic acrylate oligomeric resin by Allnex;

PETIA (Pentaerythritol triacrylate) is a reactive diluent by Allnex;

DPHA (Dipentaerythritol hexaacrylates) is a reactive diluent by Allnex;

Irgacure 184: Butyl Acetate (1:1) is a photoinitiator by BASF;

BYK 306 is a wetting agent by BYK Chemie;

Butyl Acetate is a solvent by Allnex;

Desmodur N3390 is an aliphatic polyisocyanate (HDI-trimerisate) by Bayer MaterialScience AG;

Dibutyl tin dilaurate-0.1wt % (ml) is a catalyst by Sigma Aldrich;

MIBK-ST is a solvent based (methyl isobutyl ketone) silica nanoparticle dispersion by Nissan Chemical;

### 1. UV-Patternable Hard-Coating (UPHC) Formulations

1.a) Water-Borne Formulation 1

| | Solid | | Weight in |
|---|---|---|---|
| Components | Content (%) | Weight (g) | solid (g) |
| Bayhydrol UV XP 2720/1 | 40% | 24.3 | 9.7 |
| Bayhydrol UH XP 2648 | 35% | 3.9 | 1.4 |
| 4-Hydroxy-4-Methyl-Pentanone | 100% | 2.0 | 0.0 |
| 1-Methoxy-2-propanol | 100% | 2.0 | 0.0 |
| Tegoglide 410 | 100% | 0.2 | 0.2 |
| BYK 346 | 100% | 0.1 | 0.1 |
| Irgacure 500 | 100% | 0.3 | 0.3 |
| Borchi-gel 625 | 40% | 0.2 | 0.1 |

A water-borne formulation, consisting largely of a UV curable polyurethane dispersion, co-solvents such as 4-hydroxy-4-methyl-pentanone, 1-methoxy-2-propanol, and additives such as wetting agents, photo-initiators and amines to control the pH levels, was stirred with an overhead rod stirrer for 5 min, to form a formulation of 36% solid content by weight.

1.b) Solvent-Borne Formulation 1

| Components | Solid Content (%) | Weight in solid (g) |
|---|---|---|
| Ebecryl 1200 | 100 | 92.4 |
| Desmodur N3390 | 90 | 0.4 |
| Dibutyl tin dilaurate | 100 | 0.5 |
| PETIA | 100 | 5.0 |
| Igracure 184 | 100 | 1.0 |
| BYK306 | 100 | 0.7 |

A mixture of acrylate monomers or oligomers and isocyanates were dissolved in an organic solvent, such as butyl acetate, with additives such as wetting agents and photo-initiators, to form a formulation of 20% solid content by weight (Table 3). The mixture was stirred with an overhead rod stirrer for 5 min.

1.c) Solvent-Bome Formulation 2

| Components | Solid Content (%) | Weight in solid (g) |
|---|---|---|
| Ebecryl 1200 | 100 | 77.8 |
| MIBK-ST | 30 | 16.7 |
| DPHA | 100 | 4.1 |
| Igracure 184 | 100 | 0.8 |
| BYK306 | 100 | 0.6 |

A high molecular weight acrylate, such as Ebecryl1200 (Cytec industries Inc.), UV reactive monomers such as DPHA, silica-based nanoparticles such as MIBK-ST from Nissan Chemical, were dissolved in an organic solvent, such as butyl acetate, with additives such as wetting agents and photo-initiators, to form a formulation of 20% solid content by weight (Table 5). The mixture was stirred with an overhead rod stirrer for 5 min.

### 2. Reference Example 1

The Coated Film with Substrate/UV-Curable, Patternable Hard-Coat (UPHC) (FIG. 1d), where UPHC is Based on 1.b) Solvent-Borne Formulation 1

UPHC coating process: The formulation was coated on the base polymer substrate, in this example a PET film, by the roll-to-roll process, with the feedstock fed in by methods that includes kiss-coating. The film was pre-treated by corona at 100W. The web after being coated with a single layer of the hard-coating formulation, was passed through the oven running at above room temperature, such as 130° C., during which the solvent was removed by evaporation. The duration of heating of the web by the oven was about 6 minutes. The dried film was tested for block resistance and optical properties.

Patterning process: The as-prepared UPHC-coated film was cut into a 9 cm by 9 cm piece and exposed to UV radiation at a dosage of between 800 and 2400 mJ/cm², through a shadow mask or photo mask. The UV-exposed film now consisted of areas that were exposed and areas that were unexposed to UV radiation, as determined by the metallic patterns on the mask. The film was then soaked in a solvent, such as dimethylformamide (DMF), under ultrasonic agitation for 15 min. After development, the film was rinsed with a low boiling point solvent, such as isopropyl alcohol, and placed into the oven for drying at 100° C. The dried film was tested for its optical properties for both the UV-cured and uncured areas of the UPHC as shown in below table. The patterns, thus formed on the UPHC, were observed under the microscope and images were recorded (FIG. 3). The patterned areas that were not removed by the solvent were areas of UPHC exposed to UV radiation and had been UV-cured.

TABLE
Optical properties before and after
pattern development for Ref. Ex. 1

| | | Trans | Haze | |
|---|---|---|---|---|
| Sample | b* | (%) | (%) | Remarks |
| Ref. Ex. 1 | 0.79 | 91.5 | 0.2 | Bare PET film |
| Ref. Ex. 1 | 0.77 | 91.4 | 0.5 | Thermally-dried areas (UPHC on PET) |
| | | | | before development |
| Ref. Ex. 1 | 0.81 | 91.4 | 0.5 | UV-cured areas before development |
| Ref. Ex. 1 | 0.77 | 91.3 | 0.6 | Thermally-dried areas after |
| | | | | development |
| Ref. Ex. 1 | 0.80 | 91.3 | 0.7 | UV-cured areas after development |

### 3. Reference Example 2

The Coated Film with Substrate/UPHC (FIG. 1d), where UPHC is Based on 1.c) Solvent-Borne Formulation 2

UPHC coating process: The formulation was coated on the base polymer substrate, in this example a HC PET film, by the roll-to-roll process, with the feedstock fed in by methods that includes kiss-coating. The film was pre-treated by corona at 100W. The web, after being coated with a single layer of the hard-coating formulation, was passed through the oven running at above room temperatures, such as 130° C., during which the solvent was removed by evaporation. The duration of heating of the film by the oven was about 6 minutes. The dried film was tested for block resistance and optical properties.

Patterning process: The as-prepared UPHC-coated films was cut into a 9 cm by 9 cm piece and exposed to UV radiation at a dosage of 800 to 2400 mJ/cm², through a photo-mask. The UV-exposed film now consisted of areas that were exposed and areas that were unexposed to UV radiation, as determined by the chrome patterns on the photo-mask. The film was then soaked in dimethylformamide (DMF) under ultrasonic agitation for 15 min. After development, the film was rinsed with a low boiling point solvent, such isopropyl alcohol, and placed into the oven for drying at 100° C. The dried film was tested for its optical properties for both the UV-cured and uncured areas of the UPHC as shown in below Table. The patterns, thus formed on the UPHC, were observed under the microscope and images were recorded (FIG. 4 and FIG. 5). The patterned areas that were not removed by the solvent were areas of UPHC exposed to UV radiation and had been UV-cured.

TABLE
Optical properties before and after
pattern development for Ref. Ex. 2

| | | Trans | Haze | |
|---|---|---|---|---|
| Sample | b* | (%) | (%) | Remarks |
| Ref. Ex. 2 | 0.79 | 91.45 | 0.2 | Bare PET film |
| Ref. Ex. 2 | 0.76 | 91.60 | 0.5 | Thermally-dried areas (UPHC on PET) |
| | | | | before development |
| Ref. Ex. 2 | 0.83 | 91.53 | 0.5 | UV-cured areas before development |
| Ref. Ex. 2 | 0.78 | 91.43 | 0.3 | Thermally-dried areas after |
| | | | | development |
| Ref. Ex. 2 | 0.85 | 91.50 | 0.4 | UV-cured areas after development |

### 4. Reference Example 3

The Coated Film with Substrate/UPHC (FIG. 1d), where UPHC is Based on 1.a) Water-Borne Formulation 1

UPHC coating process: The formulation was coated on the base polymer substrate, in this example a PET film, by the roll-to-roll process, with the feedstock fed in by methods that includes kiss-coating. The film was pre-treated by corona at 150W. The web after being coated with a single layer of the hard-coating formulation, was passed through the oven running at above room temperatures, such as 120° C., during which the solvent was removed by evaporation. The duration of heating of the film by the oven was about 6 minutes. The dried film was tested for block resistance and optical properties.

Patterning process: The as-prepared UPHC-coated films were cut into a 9 cm by 9 cm piece and exposed to UV radiation at a dosage of between 800 and 2400mJ/cm², through a photo-mask. The UV-exposed film now consisted of areas that were exposed and areas that were unexposed to UV radiation, as determined by the chrome patterns on the photo-mask. The film was then soaked in a solvent, such as dimethylformamide (DMF), under ultrasonic agitation for 15 min. After development, the film was rinsed with a low boiling point solvent, such as isopropyl alcohol, and placed into the oven for drying at 100° C., for 10 minutes. The dried film was tested for its optical properties for both the UV-cured and uncured areas of the UPHC as shown in below Table. The patterns, thus formed on the UPHC, were observed under the microscope and images were recorded (FIG. 6). The patterned areas that were not removed by the solvent were areas of UPHC exposed to UV radiation and had been UV-cured.

TABLE
Optical Properties of UPHC coated film for Ref. Ex. 3

| | | Trans | Haze | |
|---|---|---|---|---|
| Sample | b* | (%) | (%) | Remarks |
| Ref. Ex. 3 | 0.82 | 91.4 | 6.7 | Thermally-dried areas before |
| | | | | development |

### 5. Reference Example 4

The Coated Films with Substrate/Ag Nanowire Coating (FIG. 1a)

Formulation of silver nanowire coating: Precursor 1-In a 250 ml round bottom flask, 10 g of hydroxyl propyl methyl cellulose (HPMC) was added to 75.5 ml of heated water (80-85 ° C.) under stirring. The hotplate was turned off and the HPMC and water mixture was stirred continuously to disperse the HPMC. 124.5 ml of chilled water was added to the mixture and stirred at vigorously for 20 minutes. The mixture was filtered through a 5 μm filter to remove undissolved particles.

Precursor 2-In a 100 ml round bottom flask, 2 g of Zonyl FSO-100 Fluorosurfactant α-Fluoro-Ω-(2-hydroxyethyl) poly (difluoromethylene) polymer with polyethylenglycol (1:1) and 18.5 ml of water was added. The mixture was heated to 70° C. to dissolve Zonyl FSO-100.

A nanowire dispersion ranging from 0.10-0.25 wt % silver nanowires was formulated by combining 0.22-0.55 ml of silver nanowire, 0.094 ml of precursor 1, 0.0016 ml of precursor 2 and 4.36-4.69 ml of water was added to sample vial. The suspension was stirred at ambient conditions for at least 15 minutes.

Silver nanowire coating Process: A hard coated PET substrate was treated with plasma for 90 s. The above defined Silver nanowire formulation was coated on the PET substrate using the automatic bar coater, 15-20 μm bar at 30 mm/s speed. The coating was dried in the oven at 80° C. for 30 minutes. An optically clear conductive layer was obtained. Sheet resistance, transmittance and haze of sample were analyzed as shown in below table.

TABLE
Optical properties and sheet resistance for Ref. Ex. 4

| | b* | Transmit- | Haze | Sheet Resistance |
|---|---|---|---|---|
| Sample | value | tance (%) | (%) | (Ω/□) |
| Ref. Ex. 4 | 0.7 | 90.6 | 0.6 | 437 |
| Ref. Ex. 4 | 0.9 | 90.5 | 0.7 | 260 |
| Ref. Ex. 4 | 0.9 | 90.1 | 0.9 | 110 |
| Ref. Ex. 4 | 1.2 | 89.1 | 1.5 | 56 |

### 6. Reference Example 5

Comparative Examples for Patterning Ag Nanowire Coated Films by Strong Etchants

Formulation of silver nanowire was prepared as described in Ref. Ex. 4, Precursor 1. This formulated Ag NW dispersion was used to coat all PET samples for this example.

Formulation of UPHC was prepared as described in reference example 1.

Silver nanowire coating Process: A hard-coated PET substrate was treated with plasma for 90 s. Silver nanowire formulations was coated on the hard-coated PET substrate using the automatic bar coater, 15-μm coil bar at 30 min/s. The coating was dried in the oven at 100° C. for 30 minutes.

UPHC coating process: UPHC formulation was coated on top of the silver nanowire layer using the automatic bar coater, 4-μm coil bar at a speed of 30 mm/s. The coating was dried in the oven at 100° C. for 30 minutes,

Patterning Process: A shadow mask was placed on top of the coating. The coating is cured under UV at 100% UV lamp power and 2400 mJ/cm ² power density. The coated films with one half thermal-cured and the other half UV-cured were soaked in 5 different etchants separately, as listed in table 5, for 1 minute, followed by soaking and rinsing in distilled water and dried by air-dryer. The optical and electrical properties of the pair of thermally-cured and UV-cured films were measured at each step of the film treatment, as shown in below table.

Results show that Transene Ag Etchant, strong acids like HNO₃ and oxidizer like KMnO₄ are too strong for UPHC coating and are capable of destroying the whole film's conductivity, while H₃PO₄, under this experimental condition is not strong enough to do the patterning.

TABLE
Optical properties before and after pattern development for Ref. Ex. 5

| | Trans. | Haze | Sheet Resistance | | |
|---|---|---|---|---|---|
| Sample | (%) | (%) | (Ω/□) | Remarks | Etchants |
| Ref. Ex. 5 | — | — | 193 | Ag NW coated film | 1% HNO₃ + |
| Ref. Ex. 5 | 85.7 | 3.9 | 342 | UPHC thermal drying at 100° C. | 10 ppm |
| | | | | for 30 minutes | KMnO₄ |
| Ref. Ex. 5 | 85.0 | 3.8 | ∞ | UPHC thermal drying, etched | |
| Ref. Ex. 5 | 86.6 | 3.3 | ∞ | UPHC UV-cured, etched | |
| Ref. Ex. 5 | — | — | 134 | Ag NW coated film | Transene Ag |
| Ref. Ex. 5 | 87.5 | 3.4 | 120 | UPHC thermal drying at 100° C. | Etchant |
| | | | | for 30 minutes | |
| Ref. Ex. 5 | 91.3 | 0.6 | ∞ | UPHC thermal drying, etched | |
| Ref. Ex. 5 | 90.3 | 1.0 | ∞ | UPHC UV-cured, etched | |
| Ref. Ex. 5 | — | — | 266 | Ag NW coated film | 14% HNO₃ + |
| Ref. Ex. 5 | 86.3 | 3.6 | 303 | UPHC thermal drying at 100° C. | 14.8% HCl |
| | | | | for 30 minutes | |
| Ref. Ex. 5 | 88.6 | 3.1 | ∞ | UPHC thermal drying, etched | |
| Ref. Ex. 5 | 87.1 | 3.2 | ∞ | UPHC UV-cured, etched | |
| Ref. Ex. 5 | — | — | 258 | Ag NW coated film | 28% NMP + |
| Ref. Ex. 5 | 85.9 | 3.8 | 668 | UPHC thermal drying at 100° C. | 10% NH₄I + |
| | | | | for 30 minutes | 1% I₂ |
| Ref. Ex. 5 | 91.0 | 0.9 | ∞ | UPHC thermal drying, etched | |
| Ref. Ex. 5 | 90.1 | 1.3 | ∞ | UPHC UV-cured, etched | |
| Ref. Ex. 5 | — | — | 267 | Ag NW coated film | |
| Ref. Ex. 5 | 86.4 | 4.1 | 253 | UPHC thermal drying at 100° C. | 85% H₃PO₄ |
| | | | | for 30 minutes | |
| Ref. Ex. 5 | 87.3 | 4.0 | 310 | UPHC thermal drying, etched | |
| Ref. Ex. 5 | 86.7 | 4.1 | 292 | UPHC UV-cured, etched | |

### 7. Example 1:

The Coated Film with Substrate/UPHC/ITO (FIG. 1c), where UPHC is Based on 1.c) Solvent-Borne Formulation 2

UPHC formulation and coating process is as same as in reference example 2.

ITO sputtering process: The as-prepared UPHC-coated film from example 3 was cut into a 9 cm by 9 cm piece which was then placed in the sputtering chamber for depositing a layer of indium tin oxide (ITO), of about 25 nm thick, over the UPHC. The ITO deposition on the UPHC-coated film was done at 140° C., 100 W, 5 mTorr, in an environment of 10:1 Ar:N₂, over 360 seconds. After a thin layer of ITO (about 25nm) was deposited on the UPHC, the film was observed visually for any defects due to sputtering and the optical properties of the film were measured.

Patterning process: The film was then exposed to UV radiation, at a dosage of between 800 to 2400 mJ/cm², through a photo-mask. The UV-exposed film now consisted of areas that were exposed and areas that were unexposed to UV radiation, as determined by the chrome patterns on the photo-mask. The film was then soaked in dimethylformamide (DMF) under ultrasonic agitation for 15 min. After development, the film was rinsed with a low boiling point solvent, such as isopropyl alcohol, and placed into the oven for drying at 100° C. The dried film was tested for its optical properties for both the UV-cured and uncured areas of the UPHC as shown in below table. The patterns, thus formed on the UPHC, were observed under the microscope and images were recorded (FIG. 7).

TABLE
Optical Properties and sheet resistance before
and after pattern development for Ex. 1

| | | | | Sheet | |
|---|---|---|---|---|---|
| | | Trans. | Haze | resistance | |
| Sample | b* | (%) | (%) | (Ω/□) | Remarks |
| Ex. 1 | 0.28 | 91.9 | 0.1 | — | Before ITO deposition |
| Ex. 1 | 3.92 | 85.4 | 0.3 | 296 | After ITO deposition |
| Ex. 1 | 0.22 | 91.7 | 0.5 | ∞ | After developing |
| | | | | | (thermally-dried areas) |
| Ex. 1 | 3.80 | 85.2 | 0.4 | 264 | After developing (UV- |
| | | | | | cured areas) |

### 8. Example 2

The Coated Film with Substrate/UPHC/ITO (FIG. 1c), where UPHC is Based on 1.a) Water-Borne Formulation 1

UPHC formulation and coating process are same as reference example 3.

ITO sputtering process: The as-prepared UPHC-coated PET film from reference example 4 was cut into a 9 cm by 9 cm piece which was then placed in the sputtering chamber for depositing a layer of indium tin oxide (ITO), of about 25 nm thick, over the UPHC. The ITO deposition on the UPHC-coated film was done at 140° C., 100 W, 5mTorr, in an environment of 10:1 Ar:N₂, over 360 seconds. After a thin layer of ITO was deposited on the UPHC, the film was observed visually for any defects due to sputtering and the optical properties of the film were measured.

Patterning process: The film was then exposed to UV radiation, at a dosage of between 800 and 2400 mJ/cm², through a photo-mask. The UV-exposed film now consisted of areas that were exposed and areas that were unexposed to UV radiation, as determined by the chrome patterns on the photo-mask. The film was then soaked in a solvent, such as dimethylformamide (DMF), under ultrasonic agitation for 15 min. After development, the film was rinsed with a low boiling point solvent, such as isopropyl alcohol, and placed into the oven for drying at 100° C., for about 10 minutes. The dried film was tested for its optical properties for both the UV-cured and uncured areas of the UPHC as shown in below Table. The patterns, thus formed on the UPHC, were observed under the microscope and images were recorded (FIG. 8).

TABLE
Optical Properties and sheet resistance before
and after pattern development for Ex. 2

| | | | | Sheet | |
|---|---|---|---|---|---|
| | | Trans | Haze | resistance | |
| Sample | b* | (%) | (%) | (Ω/□) | Remarks |
| Ex. 2 | 0.82 | 91.4 | 0.7 | — | Before ITO deposition |
| Ex. 2 | — | — | 1.2 | 235 | After ITO deposited on |
| | | | | | thermally-dried UPHC |
| Ex. 2 | — | — | 1.2 | 235 | After ITO deposited on UV- |
| | | | | | cured UPHC |
| Ex. 2 | — | — | 0.7 | ∞ | After developing (thermally- |
| | | | | | dried areas) |
| Ex. 2 | — | — | 1.4 | 246 | After developing (UV-cured |
| | | | | | areas) |

### 9. Example 3

The Coated Film with Substrate/UPHC/PEDOT (FIG. 1c), where UPHC is Based on 1.c) Solvent-Borne Formulation 2

UPHC formulation and coating process are the same as reference example 2.

PEDOT coating processing: The as-prepared UPHC-coated PET film from reference example 3 was cut into a 9 cm by 9 cm piece. A layer of PEDOT was coated over the UPHC by using the film applicator at a speed of 30 mm/s and a 4 μm Meyer rod. After a thin layer of PEDOT was coated on the UPHC and dried in the oven at 100° C. for 10 minutes, the film was observed visually for any defects and the optical properties of the film were measured.

Patterning process: The film was then exposed to UV radiation, at a dosage of between 800 and 2400 mJ/cm², through a photo-mask. The UV-exposed film now consisted of areas that were exposed and areas that were unexposed to UV radiation, as determined by the chrome patterns on the photo-mask. The film was then soaked in a solvent, such as dimethylformamide (DMF), under ultrasonic agitation for 15 minutes. After development, the film was rinsed with a low boiling-point solvent, such as isopropyl alcohol, and placed into the oven for drying at 100° C., for about 10 minutes. The dried film was tested for its optical properties for both the UV-cured and uncured areas of the UPHC as shown in below Table.

TABLE
Optical Properties and sheet resistance before
and after pattern development for Ex. 3

| | | | | Sheet | |
|---|---|---|---|---|---|
| | | Trans | Haze | resistance | |
| Sample | b* | (%) | (%) | (Ω/□) | Remarks |
| Ex. 3 | 0.83 | 91.5 | 0.4 | — | Before coating with PEDOT |
| Ex. 3 | 0.30 | 87.2 | 1.4 | 284 | After coating thermally- |
| | | | | | dried UPHC with PEDOT |
| Ex. 3 | 0.39 | 87.5 | 1.3 | 325 | After coating UV-cured |
| | | | | | UPHC with PEDOT |
| Ex. 3 | 0.79 | 91.4 | 0.5 | — | After developing (thermally- |
| | | | | | dried areas) |
| Ex. 3 | 0.73 | 88.9 | 0.9 | 359 | After developing (UV-cored |
| | | | | | areas) |

### 10. Example 4

The Coated Film with Substrate/UPHC/PEDOT (FIG. 1c), where UPHC is based on 1.a) Water-Borne Formulation 1

UPHC formulation and coating process are same as reference example 3.

PEDOT coating process: The as-prepared UPHC-coated PET film from reference example 4 was cut into a 9 cm by 9 cm piece. A layer of PEDOT (Clevios-FET from Heraeus) was coated over the UPHC by using the film applicator at 30 mm/s coating speed and a 4 μm Meyer rod. After a thin layer of PEDOT was coated on the UPHC and dried in the oven at 100° C. for 10 minutes, the film was observed visually for any defects and the optical properties of the film were measured.

Patterning process: The film was then exposed to UV radiation, at a dosage of between 800 and 2400 mJ/cm², through a photo-mask. The UV-exposed film now consisted of areas that were exposed and areas that were unexposed to UV radiation, as determined by the chrome patterns on the photo-mask. The film was then soaked in a solvent, such as dimethylformamide (DMF), under ultrasonic agitation for 15 minutes. After development, the film was rinsed with a low boiling-point solvent, such as isopropyl alcohol, and placed into the oven for drying at 100° C., for about 10 minutes. The dried film was tested for its optical properties for both the UV-cured and uncured areas of the UPHC as shown in below Table. The patterns, thus formed on the UPHC, were observed under the microscope and images were recorded (FIG. 9).

TABLE
Optical Properties and sheet resistance before
and after pattern development for Ex. 4

| | | | | Sheet | |
|---|---|---|---|---|---|
| | | Trans | Haze | resistance | |
| Sample | b* | (%) | (%) | (Ω/□) | Remarks |
| Ex. 4 | — | — | — | — | Before coating with PEDOT |
| Ex. 4 | 0.27 | 87.2 | 0.7 | 309 | After coating thermally- |
| | | | | | dried UPHC with PEDOT |
| Ex. 4 | 0.27 | 87.2 | 0.7 | 363 | After coating UV-cured |
| | | | | | UPHC with PEDOT |
| Ex. 4 | — | — | — | — | After developing (thermally- |
| | | | | | dried areas) |
| Ex. 4 | 0.47 | 87.3 | 0.7 | 376 | After developing (UV-cured |
| | | | | | areas) |

### 11. Example 5

The Coated Film with Substrate/Ag Nanowire Coating/UPHC (FIG. 1b), where UPHC is Based on 1.b) Solvent-Borne Formulation 1

Formulation of silver nanowire was prepared as described in Ref. Ex. 4.

Silver nanowire coating process: A HC PET substrate was treated with plasma for 90 s. The silver nanowire formulation was coated on the PET substrate using the automatic bar coater, with a 20 μm-bar at a speed of 30 mm/s. The coating was dried in the oven at 80° C. for 30 minutes. An optically clear conductive layer with an optical transmission (T) of 89.3% and haze (H) of about 1.8% was obtained. The conductive layer had a sheet resistance of about 432Ω/□.

UPHC formulation is prepared as described in reference example 1.

UPHC coating process: UPHC formulation was coated on top of the silver nanowire layer using the automatic bar coater, with a 4 μm-bar at a speed of 30 mm/s. The coating was dried in the oven at 100° C. for 30 minutes. An optically clear conductive layer with an optical transmission (T) of 88.9% and haze (H) of about 2.4% was obtained. The conductive layer had a sheet resistance of about 975Ω/□.

Patterning Process: A shadow mask was placed on top of the coating. The coating was cured by UV radiation at 100% UV lamp power and power density of 2400 mJ/cm². The mask was removed and the sample was washed with acetone and wiped. Transmittance, haze and sheet resistance of sample were analyzed for the UV-cured and thermally-cured areas as shown in below Table.

TABLE
Optical Properties and sheet resistance before
and after pattern development for Ex. 5

| | | | Sheet | |
|---|---|---|---|---|
| | Trans. | Haze | Resistance | |
| Sample | (%) | (%) | (Ω/□) | Remarks |
| Ex. 5 | 89.3 | 1.8 | 432 | Ag NW thermal drying at 80° C. |
| | | | | for 30 minutes |
| Ex. 5 | 88.9 | 2.4 | 975 | UPHC thermal drying at 100° C. |
| | | | | for 30 minutes |
| Ex. 5 | 88.6 | 2.7 | 575 | UPHC UV-cured |
| Ex. 5 | 91.5 | 1.0 | ∞ | UPHC thermal drying at 100° C. |
| | | | | for 30 minutes and solvent washed |
| Ex. 5 | 88.8 | 2.4 | 753 | UPHC UV-cured and solvent- |
| | | | | washed |

### 12. Example 6

The Coated Film with Substrate/UPHC/Ag Nanowire Coating (FIG. 1c), where UPHC is Based on 1.b) Solvent-Borne Formulation 1

Formulation of silver nanowire was prepared as described in Ref Ex. 4.

UPHC formulation is prepared as described in reference example 1.

UPHC/Silver nanowire coating process: A HC PET substrate was treated with plasma for 90s. UPHC formulation was coated on the PET using an automatic bar coater, with a 4-μm coil bar at a speed of 30 mm/s. The coating was partially dried in the oven at 100° C. for 15 minutes. Then a layer of silver nanowire was coated on top of the 1st UPHC layer. Silver nanowire formulation was coated using a 20 μm coil bar at 30 mm/s. The coating was dried in the oven at 100° C. for 15 minutes. An optically clear conductive layer with an optical transmission (T) of 85.9% and haze (H) of about 4.5% was obtained. The conductive layer had a sheet resistance of about 1280Ω/□ as shown in below Table.

Patterning process: A shadow mask was placed on top of the coating. The coating was cured under UV at 100% UV lamp power, 2400 mJ/cm² power density. The mask was removed and the sample was immersed in acetone for 30 minutes before it was removed and dried in the oven. Sheet resistance, transmittance and haze of the sample were analyzed.

TABLE
Optical Properties and sheet resistance before
and after pattern development for Ex. 6

| | | | Sheet | |
|---|---|---|---|---|
| | Trans. | Haze | Resistance | |
| Sample | (%) | (%) | (Ω/□) | Remarks |
| Ex. 6 | 85.9 | 4.5 | 1280 | UPHC + Ag NW after thermal |
| | | | | drying at 100° C. for 15 minutes |
| Ex. 6 | 85.3 | 4.9 | ∞ | UPHC + Ag NW thermally dried, |
| | | | | solvent-washed 30 minutes |
| Ex. 6 | 85.5 | 3.7 | 2464 | UPHC + Ag NW UV-cured, |
| | | | | solvent-washed 30 minutes |

### 13. Example 7

The Coated Film with Substrate/Ag Nanoparticle Coating/UPHC (FIG. 1b), where UPHC is based on 1.b) Solvent-Borne Formulation 1

Formulation of UPHC is prepared as described in reference example 1.

The coated film with Ag nanoparticles coating was a SANTE™ film from CIMA Nanotech.

UPHC coating process: A single layer of the UPHC formulation was applied onto SANTE™ film, using a 4-μm Meyer rod and automatic film applicator at a speed of 30 mm/s. The UPHC was then cured in the oven at 100° C., for 30 minutes.

Patterning process: In the patterning process, a shadow mask was placed on top of the coating. The coating was cured under UV at 100% UV lamp power and 2400 mJ/cm² power density. The coated film with one half thermally-cured and the other half UV-cured was soaked in the Silver Etchant TFS (Transene Company, Inc) for 1 minute, followed by rinsing in water and drying by hot air from dryer. The optical and electrical properties of the pair of thermal dry and UV-cured films were measured at each step of the film treatment as shown in below Table.

Results show that the UV-cured CIMA film had its surface conductivity preserved after being etched while the thermally dried CIMA film had lost its surface conductivity after being etched. This effect could be used effectively for the purpose of patterning conductive films, using a UPHC.

TABLE
Optical Properties and sheet resistance before
and after pattern development for Ex. 7

| | | | Sheet | | |
|---|---|---|---|---|---|
| | Trans. | Haze | Resistance | | |
| Sample | (%) | (%) | (Ω/□) | Remarks | Etchants |
| Ex. 7 | — | — | 12.5 | SANTA ™ film | — |
| | | | | from CIMA | |
| | | | | Nanotech | |
| Ex. 7 | 81.7 | 8.7 | 10.2 | UPHC thermally | — |
| | | | | dried | |
| Ex. 7 | 81.7 | 8.7 | 9.0 | UPHC UV-cured | — |
| Ex. 7 | 82.2 | 8.9 | ∞ | UPHC thermally | Transene |
| | | | | dried, washed | Ag Etchant |
| Ex. 7 | 82.0 | 9.3 | 13.4 | UPHC UV-cured, | Transene |
| | | | | washed | Ag Etchant |

The inventions relates to

1 Substrates coated with at least one transparent conductive material layer and at least one hard-coating layer, characterized in that the hard-coating layer is a block-resistant thermoplastic layer and is end-cured by subsequent polymerization induced by actinic radiation comprising:.
A) one or more monomeric or polymeric compounds that carry at least one functional group, that react with ethylenically unsaturated compounds under the action of actinic radiation, with polymerization, which compounds
   A1) contain at least one chemical function a) suitable for polyaddition with component B) and different from b) and/or
   A2) do not contain chemical function a) and optionally
B) one or more compounds containing at least one chemical function b) suitable for polyaddition with component A1) and different from a), which compounds
   B1) do not contain ethylenically unsaturated double bonds and/or
   B2) contain ethylenically unsaturated double bonds and
C) silica nanoparticles,
D) photoinitiators,
E) additives such as stabilisers, catalysts, wetting agents and other auxiliary substances and additives,
F) non-functional polymers and/or fillers.

2. Substrates according to 1., characterized in that said substrates are directly in contact with said transparent conductive material and the hard coating being in contact with said transparent conductive material.

3. Substrates according to 1., characterized in that said substrates are directly in contact with the hard-coating and said transparent conductive material being in contact with said hard-coating.

4. Substrates according to any of paragraphs 1. to 3., characterized in that it encompasses inorganic substrates, in particular ceramics or mineral glass; thermosetting polymers and thermoplastic polymers, in particular polyacrylates, polymethacrylates, polycarbonates, thermoplastic polyurethanes, polyesters, polyethers, polyolefins, polyamides, copolymers of different polymers and blends of different polymers, and coated substrates.

5. Substrates according to any of paragraphs 1. to 4., characterized in that said transparent conductive material contains nanoparticles, nanowires, conductive polymers, transparent conductive oxides, carbon or metal based nanomaterials and nanocomposites.

6. Substrates according to any of paragraphs 1. to 5., characterized in that the substrate is patterned to obtain conductive areas and non-conductive areas.

7. Substrates according to any of paragraphs 1. to 6., characterized in that substrate is a film. 8. Substrates according to 7., characterized in that the film carries more than one coatings according to claim I on top of one another.

9. Substrates according to 7. or 8., characterized that at least one of the coating layers has a pattern.

10. Substrates according to 7. to 9., characterized in that the film is coated according to claim 1 on both sides.

11. Substrates according to 7. or 10., characterized in that the film is at least patterned on one side.

12. Process for the preparation of a coated substrate according to anyone of paragraphs 1. to 11., characterized by the steps in the following sequence:
(a) coating said substrate with a transparent conductive material,
(b) coating said transparent conductive material with a hard-coating precursor,
(c) thermally curing said hard-coating precursor,
(d) end-curing said hard-coating.

13. Process according to 12., characterized by the steps in the following sequence:
(a1) coating said substrate with a hard-coating precursor,
(b1) thermally curing said hard-coating precursor,
(c1) coating said thermally cured hard-coating with a transparent conductive material,
(d1) end-curing said hard coating or
(e1) coating said substrate with a hard-coating precursor,
(f1) thermally curing said hard-coating precursor,
(g1) end-curing said hard coating,
(h1) coating said thermally cured hard-coating with a transparent conductive material.

14. Process according to 12. or 13., characterized in that in step (d) said thermally cured hard-coating is patterned by applying a physical mask on the top surface during end-curing with actinic radiation and subsequent solvent washing of the coated substrate.

1.-12. (canceled)

13. A coated substrate comprising at least one transparent conductive material layer and at least one UV-patternable hard-coating layer, wherein the hard-coating layer is a block-resistant thermoplastic layer and is end-cured by actinic radiation comprising:
A) one or more monomeric or polymeric compounds that carry at least one functional group, that react with ethylenically unsaturated compounds under the action of actinic radiation, with polymerization, which compounds
A1) contain at least one chemical function a) suitable for polyaddition with component B) and different from b) and/or
A2) do not contain chemical function a) and optionally
B) one or more compounds containing at least one chemical function b) suitable for polyaddition with component A1) and different from a), which compounds
B1) do not contain ethylenically unsaturated double bonds and/or
B2) contain ethylenically unsaturated double bonds and
C) silica nanoparticles,
D) photoinitiators,
E) additives such as stabilisers, catalysts, wetting agents and other auxiliary substances and additives,
F) non-functional polymers and/or fillers,
wherein the substrate comprises conductive areas and non-conductive areas that form patterns and at least one of the coating layers has a pattern.

14. The substrate according to claim 13, wherein the substrate is directly in contact with the transparent conductive material and the hard coating is in contact with the transparent conductive material.

15. The substrate according to claim 13, wherein the substrate is directly in contact with the hard-coating and the transparent conductive material is in contact with the hard-coating.

16. The substrate according to claim 13, wherein the substrate is selected from the group consisting of inorganic substrates, thermosetting polymers, thermoplastic polymers, polyacrylates, polymethacrylates, polycarbonates, thermoplastic polyurethanes, polyesters, polyethers, polyolefins, polyamides, copolymers of different polymers, and blends of different polymers.

17. The substrate according to claim 13, wherein the transparent conductive material contains nanoparticles, nanowires, conductive polymers, transparent conductive oxides, carbon or metal based nanomaterials or nanocomposites.

18. The substrate according to claim 13, wherein the substrate is a film.

19. The substrate according to claim 18, wherein the film comprises more than one hard-coating layer on top of one another.

20. The substrate according to claim 18, wherein the film comprises a hard-coating layer on both sides.

21. The substrate according to claim 18, wherein the film has a pattern on at least one side.

22. A process for the preparation of a coated substrate with at least one transparent conductive material layer and at least one hard-coating layer, wherein the hard-coating layer is a block-resistant thermoplastic layer comprising:
A) one or more monomeric or polymeric compounds that carry at least one functional group, that react with ethylenically unsaturated compounds under the action of actinic radiation, with polymerization, which compounds
A1) contain at least one chemical function a) suitable for polyaddition with component B) and different from b) and/or
A2) do not contain chemical function a) and optionally
B) one or more compounds containing at least one chemical function b) suitable for polyaddition with component A1) and different from a), which compounds
B1) do not contain ethylenically unsaturated double bonds and/or
B2) contain ethylenically unsaturated double bonds and
C) silica nanoparticles,
D) photoinitiators,
E) additives such as stabilisers, catalysts, wetting agents and other auxiliary substances and additives,
F) non-functional polymers and/or fillers, comprising the steps in the following sequence:
(a) coating said substrate with a transparent conductive material,
(b) coating said transparent conductive material with a hard-coating precursor,
(c) thermally curing said hard-coating precursor,
(d) patterning said thermally cured hard-coating by applying a physical mask on the top surface during end-curing with actinic radiation and
(e) subsequent solvent washing of the coated substrate.

23. A process for the preparation of a coated substrate with at least one transparent conductive material layer and at least one hard-coating layer, wherein the hard-coating layer is a block-resistant thermoplastic layer comprising:
A) one or more monomeric or polymeric compounds that carry at least one functional group, that react with ethylenically unsaturated compounds under the action of actinic radiation, with polymerization, which compounds
A1) contain at least one chemical function a) suitable for polyaddition with component B) and different from b) and/or
A2) do not contain chemical function a) and optionally
B) one or more compounds containing at least one chemical function b) suitable for polyaddition with component A1) and different from a), which compounds
B1) do not contain ethylenically unsaturated double bonds and/or
B2) contain ethylenically unsaturated double bonds and
C) silica nanoparticles,
D) photoinitiators,
E) additives such as stabilisers, catalysts, wetting agents and other auxiliary substances and additives,
F) non-functional polymers and/or fillers, comprising the steps in the following sequence:
(a1) coating said substrate with a hard-coating precursor,
(b1) thermally curing said hard-coating precursor,
(c1) coating said thermally cured hard-coating with a transparent conductive material,
(d1) patterning said thermally cured hard-coating by applying a physical mask on the top surface during end-curing with actinic radiation
(e 1) and subsequent solvent washing of the coated substrate or
(f1) coating said substrate with a hard-coating precursor,
(g1) thermally curing said hard-coating precursor,
(h1) patterning said thermally cured hard-coating by applying a physical mask on the top surface during end-curing with actinic radiation,
(i1) subsequent solvent washing of the coated substrate and
(j1) coating said thermally cured hard-coating with a transparent conductive material.

24. An articles comprising the coated substrate according to claim 13.
